(19) United States
(12) Patent Application Publication
(10) Pub. No.: US 2023/0139138 A1
(43) Pub. Date: May 4, 2023

(54) CHARGE FILTER MAGNET WITH VARIABLE ACHROMATICITY

(71) Applicant: Axcelis Technologies, Inc., Beverly, MA (US)

(72) Inventors: Wilhelm Platow, Newburyport, MA (US); Shu Satoh, Byfield, MA (US); Neil Bassom, Hamilton, MA (US)

(21) Appl. No.: 17/514,262

(22) Filed: Oct. 29, 2021

(51) Int. Cl. H01J 37/317; H01L 21/265; H01J 37/08; H05H 9/00

(52) U.S. Cl. CPC H01J 37/3171; H01L 21/265; H01J 37/08; H05H 9/00; H01J 2237/31701

(57) ABSTRACT

An ion implantation system has an ion source to generate an ion beam, and a mass analyzer to define a first ion beam having desired ions at a first charge state. A first linear accelerator accelerates the first ion beam to a plurality of first energies. A charge stripper strips electrons from the desired ions defining a second ion beam at a plurality of second charge states. A first dipole magnet spatially disperses and bends the second ion beam at a first angle. A charge defining aperture passes a desired charge state of the second ion beam while blocking a remainder of the plurality of second charge states. A quadrupole apparatus spatially focuses the second ion beam, defining a third ion beam. A second dipole magnet bends the third ion beam at a second angle. A second linear accelerator accelerates the third ion beam. A final energy magnet bends the third ion beam at a third angle, and wherein an energy defining aperture passes only the desired ions at a desired energy and charge state.

### FIELD

The present disclosure relates generally to ion implantation systems, and more particularly to an ion implantation system having a small footprint and increased ion beam current at a high energy for a desired charge state.

### BACKGROUND

In the manufacture of semiconductor devices, ion implantation is used to dope semiconductors with impurities. Ion implantation systems are often utilized to dope a workpiece, such as a semiconductor wafer, with ions from an ion beam, in order to either produce n- or p-type material doping, or to form passivation layers during fabrication of an integrated circuit. Such beam treatment is often used to selectively implant the wafers with impurities of a specified dopant material, at a predetermined energy level, and in controlled concentration, to produce a semiconductor material during fabrication of an integrated circuit. When used for doping semiconductor wafers, the ion implantation system injects a selected ion species into the workpiece to produce the desired extrinsic material. When implanting ions into silicon wafers, ions generated from source materials such as antimony, arsenic, or phosphorus, for example, results in an “n-type” extrinsic material wafer, whereas a “p-type” extrinsic material wafer often results from ions generated with source materials such as boron, gallium, or indium. When implanting ions into silicon carbide (SiC) wafers, for example, nitrogen (n-dopant) and aluminum (p-dopant) are conventionally used as ion species.

A typical ion implanter includes an ion source, an ion extraction device, a mass analysis device, with or without a post acceleration section, a beam transport device, and a wafer processing device. The ion source generates ions of desired atomic or molecular dopant species. These ions are extracted from the ion source by the ion extraction device, which are typically a set of electrodes that energize and direct the flow of ions from the ion source, forming an ion beam. Desired ions are separated from the ion beam in the mass analysis device, which is typically a magnetic dipole performing mass dispersion or separation of the extracted ion beam. The beam transport device, which is typically a vacuum system containing a series of focusing and acceleration/deceleration devices, transports the analyzed ion beam to the wafer processing device while maintaining desired properties of the ion beam. Finally, semiconductor wafers are transferred in to and out of the wafer processing device via a wafer handling system, which may include one or more robotic arms, for placing a wafer to be treated in front of the analyzed ion beam and removing treated wafers from the ion implanter.

### SUMMARY

The present disclosure appreciates that significant demands for an ion implantation recipe (e.g., ion beam energy, mass, charge value, beam purity, beam current and/or total dose level of the implantation) at a high energy level call for providing a higher beam current and a sufficient beam purity that does not compromise the ion source. As such, various systems or methods for providing a high beam current along with a high beam purity are provided herewith.

Accordingly, the following presents a simplified summary of the disclosure in order to provide a basic understanding of some aspects of the disclosure. This summary is not an extensive overview of the disclosure. It is intended to neither identify key or critical elements of the invention nor delineate the scope of the invention. Its purpose is to present some concepts of the disclosure in a simplified form as a prelude to the more detailed description that is presented later.

Aspects of the disclosure facilitate high energy ion implantation processes for implanting ions into a workpiece. According to one exemplary aspect, an ion implantation system is provided having an ion source configured to form an ion beam, a beamline assembly configured to selectively transport the ion beam, and an end station is configured to accept the ion beam for implantation of ions into a workpiece.

In accordance with one example aspect of the present disclosure, the ion source defines a generated ion beam along a beamline, and a mass analyzing magnet is configured to mass analyze the generated ion beam, thereby defining a first ion beam comprising desired ions at a first charge state. A first acceleration stage (e.g., a first linear accelerator) accelerates the desired ions of the first ion beam to a plurality of first energies, and a charge stripper is configured to strip at least one electron from the desired ions of the first ion beam. Accordingly, a second ion beam comprising the desired ions at a plurality of second charge states (e.g., a Gaussian charge state distribution) is defined.

In one example, a first dipole magnet is further configured to bend the second ion beam at a first predetermined angle, thereby spatially dispersing the second ion beam. A charge defining aperture is configured to pass a desired charge state selected from the plurality of second charge states therethrough, while blocking a remainder of the plurality of second charge states from passing therethrough. A quadrupole magnet, for example, is further configured to spatially focus the second ion beam to define a third ion beam comprising the desired ions at the plurality of first energies and at the desired charge state. A second dipole magnet is further configured to bend the third ion beam at a second predetermined angle.

A second acceleration stage (e.g., a second linear accelerator), for example, is configured to accelerate the desired ions of the third ion beam to a plurality of second energies. A final energy magnet comprising an energy defining aperture is further provided, wherein the final energy magnet is configured to bend the third ion beam at a third predetermined angle. The energy defining aperture, for example, is configured to pass only the desired ions at a desired energy therethrough, thereby defining a final ion beam comprising the desired ions at the desired energy and desired charge state.

In one example, the first predetermined angle and second predetermined angle are approximately 45 degrees. In another example, a sum of the first predetermined angle and second predetermined angle is approximately 90 degrees. In yet another example, the third predetermined angle is approximately 90 degrees.

The first predetermined angle and second predetermined angle, in one example, are equal, wherein the first dipole magnet and second dipole magnet are generally mirror images of one another. In one example, an exit of the first dipole magnet and an entrance of the second dipole magnet are separated by a predetermined separation distance. The quadrupole magnet, for example, can be positioned between the first dipole magnet and second dipole magnet at approximately half the predetermined separation distance. The first predetermined angle, for example, can define a radius associated with the first dipole magnet, wherein the predetermined separation distance is less than approximately twice the radius.

The charge defining aperture, for example, is sized or otherwise configured to permit all of the plurality of first energies to pass therethrough. The charge defining aperture, for example, can be defined by an opening of the quadrupole magnet through which the second ion beam enters the quadrupole magnet. In one example, the charge defining aperture is positioned between the first dipole magnet and the quadrupole magnet along the beamline. A width of the charge defining aperture, for example, can permit only a predetermined dispersion of the plurality of first energies to pass into the quadrupole magnet. The width of the charge defining aperture, for example, can be variable.

In another example, a scanner is provided and configured to scan the final ion beam in a first direction, thereby defining a scanned ion beam. A parallelizer can be further provided and configured to parallelize and shift the scanned ion beam.

According to another example, one or more of the first acceleration stage and the second acceleration stage comprise an RF accelerator comprising one or more resonators configured to generate an accelerating RF field. In another example, one or more of the first acceleration stage and the second acceleration stage comprise a DC accelerator configured to accelerate the desired ions via a stationary DC high voltage. The first acceleration stage and the second acceleration stage can thus comprise any combination of DC and RF accelerators.

The above summary is merely intended to give a brief overview of some features of some embodiments of the present disclosure, and other embodiments may comprise additional and/or different features than the ones mentioned above. In particular, this summary is not to be construed to be limiting the scope of the present application. Thus, to the accomplishment of the foregoing and related ends, the disclosure comprises the features hereinafter described and particularly pointed out in the claims. The following description and the annexed drawings set forth in detail certain illustrative embodiments of the disclosure. These embodiments are indicative, however, of a few of the various ways in which the principles of the disclosure may be employed. Other objects, advantages and novel features of the disclosure will become apparent from the following detailed description of the disclosure when considered in conjunction with the drawings.

### BRIEF DESCRIPTION OF THE DRAWINGS

FIG. 1 is a simplified top view illustrating an ion implantation system in accordance with an aspect of the present disclosure;

FIG. 2 is a charge selector apparatus of an ion implantation system according to at least one aspect of the present disclosure;

FIG. 3 illustrates a quadrupole magnet and charge defining aperture of the charge selector apparatus of FIG. 2;

FIG. 4 illustrates another charge selector apparatus of an ion implantation system according to at least another aspect of the present disclosure;

### DETAILED DESCRIPTION

The present disclosure is directed generally toward various apparatuses, systems, and methods associated with implantation of ions into a workpiece. More specifically, the present disclosure is directed to an ion implantation system having a small footprint and increased ion beam current at a high energy for a desired charge state.

Accordingly, the present invention will now be described with reference to the drawings, wherein like reference numerals may be used to refer to like elements throughout. It is to be understood that the description of these aspects are merely illustrative and that they should not be interpreted in a limiting sense. In the following description, for purposes of explanation, numerous specific details are set forth in order to provide a thorough understanding of the present invention. It will be evident to one skilled in the art, however, that the present invention may be practiced without these specific details. Further, the scope of the invention is not intended to be limited by the embodiments or examples described hereinafter with reference to the accompanying drawings, but is intended to be only limited by the appended claims and equivalents thereof.

It is also noted that the drawings are provided to give an illustration of some aspects of embodiments of the present disclosure and therefore are to be regarded as schematic only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components in implementations according to an embodiment of the invention. Furthermore, the features of the various embodiments and examples described herein may be combined with each other unless specifically noted otherwise.

It is also to be understood that in the following description, any direct connection or coupling between functional blocks, devices, components, or other physical or functional units shown in the drawings or described herein could also be implemented by an indirect connection or coupling. Furthermore, it is to be appreciated that functional blocks or units shown in the drawings may be implemented as separate features or components in one embodiment, and may also or alternatively be fully or partially implemented in a common feature or component in another embodiment.

Ion implantation is a physical process, as opposed to diffusion, which is a chemical process that is employed in semiconductor apparatus fabrication to selectively implant dopant into a semiconductor workpiece and/or wafer material. Thus, the act of implanting does not rely on a chemical interaction between a dopant and the semiconductor material. For ion implantation, dopant atoms/molecules are ionized and isolated, sometimes accelerated or decelerated, formed into a beam, and swept across a workpiece or wafer. The dopant ions physically bombard the workpiece, enter the surface and typically come to rest below the workpiece surface in the crystalline lattice structure thereof. Commonly-owned U.S. Pat. No. 8,035,080 to Satoh describes various systems and method for increasing beam current, the contents of which are herein incorporated by reference, in their entirety.

High-energy ion implantation systems (e.g., systems configured to implant ions at energies greater than 1 MeV, such as those implemented in the formation of image sensors) are notoriously long in size. In order to minimize a footprint and save cleanroom space, RF linear accelerators (LINACs) or DC accelerator columns can be broken into sections and separated by bending magnets. The bending magnets, for example, allow the beamline to be more compact by bending the ion beam to various desired angles. For example, the beamline can be V-shaped or a generally polygonal chain.

A simple system, for example, can comprise first and second accelerator stages or LINACs separated by one bending magnet. For such an arrangement, the present disclosure appreciates that it can be advantageous to add a so-called stripper after the first acceleration stage, wherein the stripper is configured to strip electrons from ions of the ion beam, thus increasing a charge state of the ions. As such, the second acceleration stage can increase the energy by a factor equal to the charge state. Such an arrangement allows the footprint of the system to be substantially reduced, as compared to a system without a bending magnet.

The ion beam exiting the stripper, for example, contains ions of many various charge states, wherein some undesirable charge states are included in the ion beam. With the aforementioned bending magnet, such unwanted charge states can be separated from the beam path, thus preventing contamination of the ion beam. However, when separating two or more LINACs with a bending magnet, the present disclosure appreciates that the ion beam will also contain a degree of energy spread that also should be transported through the bending magnet to maintain beam current, otherwise beam currents will be substantially lower.

Such a bending magnet can be considered an achromatic system, as it is, to some degree, independent of the energy. The present disclosure appreciates that one issue associated with separating first and second LINACs while having a stripper disposed therebetween, is that on one hand, the bending magnet should filter out unwanted charge states, while on the other hand, the bending magnet should be substantially achromatic (e.g., having a low dispersion) in order to accept and pass an ion beam therethrough with an energy spread of typically 1-2%.

Thus, in accordance with one example aspect, the present disclosure employs two dipole magnets having a quadrupole magnet disposed therebetween, whereby the quadrupole magnet comprises an aperture configured to accept a predetermined energy spread, while rejecting unwanted charge states. As such, the configuration of the present disclosure provides a magnet architecture configured for filtering charges, while maintaining a substantially small footprint.

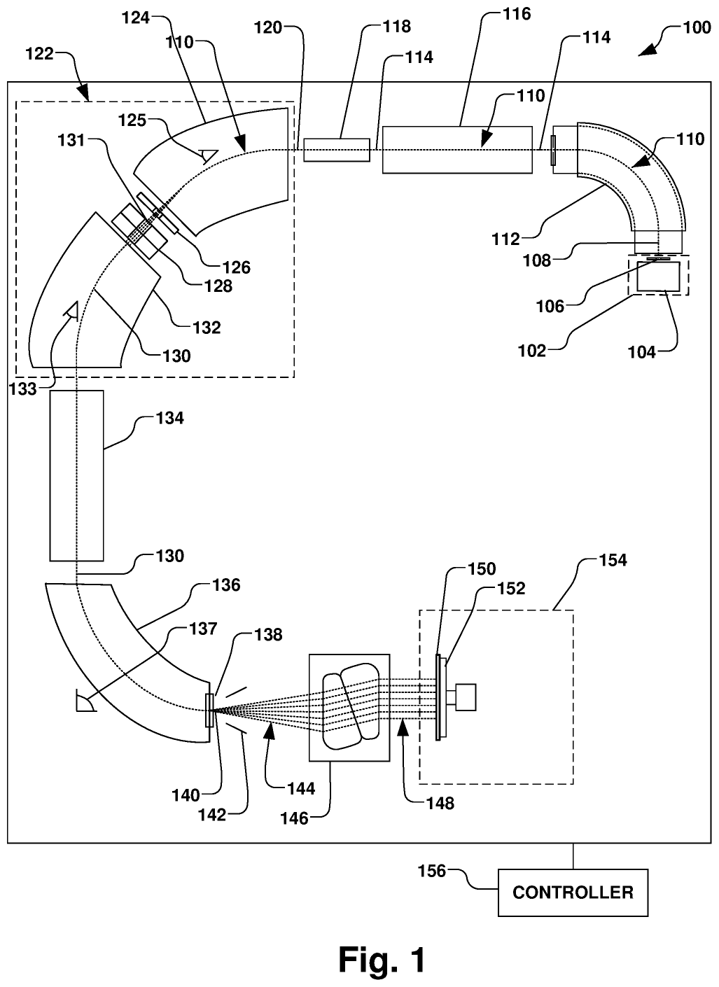

Referring now to the figures, in order to gain a better understanding of the present disclosure, FIG. 1 illustrates example ion implantation system 100 in accordance with various exemplified aspects of the present disclosure. The ion implantation system 100, for example, can sometimes be referred to as a post acceleration implanter, as will be discussed infra.

The ion implantation system 100 of FIG. 1, for example, comprises a source chamber assembly 102, whereby the source chamber assembly comprises an ion source 104 and an extraction electrode 106 configured to extract and accelerate ions from the ion source to an intermediate energy, thereby forming a generated ion beam 108 along a beamline 110. A mass analyzer 112, for example, mass analyzes the generated ion beam 108, thereby removing unwanted mass and charge ion species from the generated ion beam to define a first ion beam 114 (also called an analyzed ion beam) comprising desired ions at a first charge state (q₁). A first linear accelerator 116 (also called a first LINAC), for example, is configured to accelerate the desired ions of the first ion beam 114 to a plurality of first energies. In accordance with one example of the present disclosure, the first LINAC 116 comprises an RF linear particle accelerator in which ions are accelerated repeatedly by an RF field. Alternatively, the first LINAC 116 comprises a DC accelerator (e.g., a tandem electrostatic accelerator), in which ions are accelerated with a stationary DC high voltage.

A charge stripper 118, for example, is further provided and configured to strip at least one electron from the desired ions of the first ion beam 114, thereby defining a second ion beam 120 comprising the desired ions at a plurality of second charge states (q₂). In accordance with the present disclosure, a charge selector 122, for example, is further positioned downstream of the charge stripper 118 in order to select desired ions with a higher charge state after the stripping process.

The charge selector 122, for example, comprises a first dipole magnet 124, wherein the first dipole magnet is configured to bend the second ion beam 120 at a first predetermined angle 125, thereby spatially dispersing the second ion beam. A charge defining aperture 126 is positioned downstream of the first dipole magnet 124, wherein the charge defining aperture is configured to pass a desired charge state of the second ion beam 120 selected from the plurality of second charge states therethrough, while blocking a remainder of the plurality of second charge states of the second ion beam from passing therethrough.

The charge selector 122 further comprises a quadrupole apparatus 128 (e.g., a quadrupole magnet), for example, wherein the quadrupole apparatus is configured to spatially focus the second ion beam 120 to define a third ion beam 130 comprising the desired ions at the plurality of first energies and at the desired charge state. In one example, the charge defining aperture 126 is defined by an opening 131 of the quadrupole apparatus 128 through which the second ion beam 120 enters the quadrupole apparatus. A second dipole magnet 132 of the charge selector 122 is further configured to bend the third ion beam 130 at a second predetermined angle 133. In the present example, a sum of the first predetermined angle 125 and second predetermined angle 133 is approximately ninety degrees. For example, the first predetermined angle 125 and second predetermined angle 133 are approximately 45 degrees. It should be noted that the example angular values of the first predetermined angle 125 and second predetermined angle 133 are not to be considered limiting, and that the present disclosure contemplates various other angular values as falling within the scope of the present disclosure.

The third ion beam 130 exiting the second dipole magnet 132, for example, can be further directed to a second linear accelerator 134 in order to gain maximum energy that is higher than the original-charge state ions. For example, the second linear accelerator 134 can be configured to accelerate the desired ions of the third ion beam 130 to a plurality of second energies.

A final energy magnet 136, for example, is further provided, wherein the final energy magnet is configured to bend the third ion beam 130 at a third predetermined angle 137. The third predetermined angle 137, for example, is approximately 90 degrees. An energy defining aperture 138 of the final energy magnet, for example, is configured to pass only the desired ions at a desired energy therethrough, thereby defining a final ion beam 140 comprising the desired ions at the desired energy and desired charge state. The final energy magnet 136 is thus configured to remove unwanted energy spectrum from the accelerated third ion beam 130 emerging from the output of second linear accelerator 134 to define the final ion beam 140.

A beam scanner 142, for example, can be further provided and configured to scan the final ion beam 140 after exiting from the final energy magnet 136, whereby the final ion beam is scanned back and forth at a fast frequency to define a scanned ion beam 144. The beam scanner 142, for example, is configured to electrostatically or electromagnetically scan the final ion beam 140 to define a scanned ion beam 144.

The scanned ion beam 144 is further passed into an angle corrector lens 146, whereby the angle corrector lens 146, for example, can be configured to parallelize and shift the scanned ion beam 144 to define a parallelized final ion beam 148 for implantation into a workpiece 150 supported on a workpiece support 152. The angle corrector lens 146, for example, can comprise electromagnetic or electrostatic devices configured to shift and/or parallelize the scanned ion beam 144.

The workpiece 150 (e.g., a semiconductor wafer) can be selectively positioned in a process chamber or end station 154. In one example, the workpiece 150, for example, can be moved orthogonal to the parallelized final ion beam 148 (e.g., moving in and out of the paper) in a hybrid scan scheme to irradiate the entire surface of the workpiece 150 uniformly. It is noted that the present disclosure appreciates various other mechanisms and methods for scanning the final ion beam 140 with respect to the workpiece 150, and all such mechanisms and methods are contemplated as falling within the scope of the present disclosure.

A controller 156, for example, can be further provided to control one or more components of the ion implantation system 100, such as one or more of the ion source 104, mass analyzing magnet 112, first linear accelerator 116, charge selector 122, second linear accelerator 134, beam scanner 142, final energy magnet 136, and workpiece support 152.

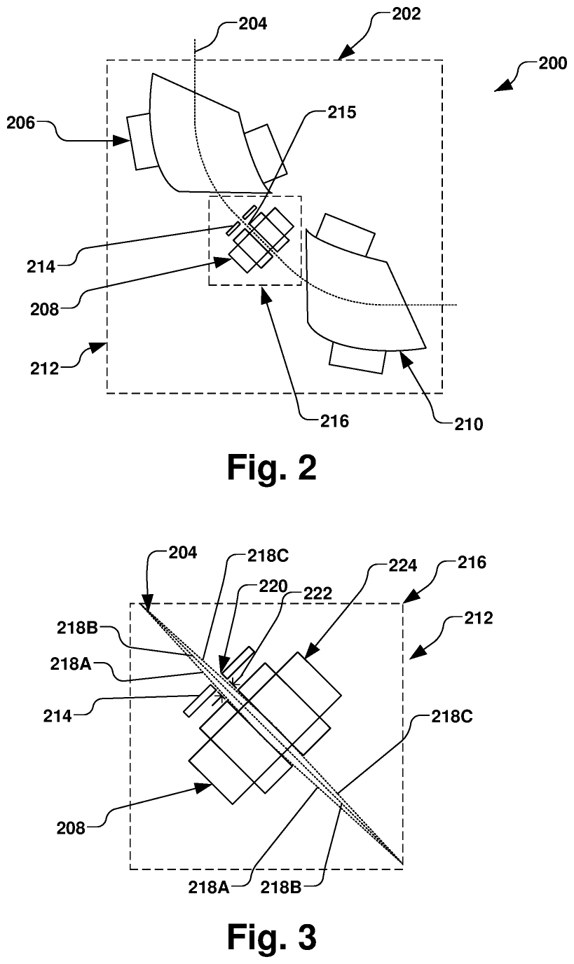

As discussed above, the ion implantation system 100 is advantageous over conventional systems by providing a minimal footprint due, at least in part, to the substantially achromatic configuration of the charge selector 122. For example, as illustrated in FIG. 2, an example 200 of a charge selector 202 having a ninety-degree bend is shown. In one non-limiting example, an ion beam 204 (e.g., the second ion beam 120 entering the charge selector 122 of FIG. 1) enters a first dipole magnet 206 having a 5% energy spread, passes through a quadrupole apparatus 208, and exits through a second dipole magnet 210, thereby generally defining an achromatic apparatus 212. The achromatic apparatus 212, for example, further comprises a charge defining aperture 214, wherein in the present example, the first dipole magnet 206 and second dipole magnet 210 are mirror images one another. In one example, the charge defining aperture 214 is defined by an opening 215 of the quadrupole apparatus 208.

FIG. 3 illustrates an enlarged view 216 of the quadrupole apparatus 208 of the achromatic apparatus 212 of FIG. 2, showing a plurality of energetic portions 218A, 2188, 218C of the ion beam 204, whereby the plurality of energetic portions of the ion beam are spatially separated or dispersed due to corresponding plurality of magnetic rigidities and dispersive properties of the first dipole magnet 206. The quadrupole apparatus 208 of the achromatic apparatus 212, for example, focuses the plurality of energetic portions 218A, 218B, 218C of the ion beam 204 such that plurality of energetic portions are not spatially separated when exiting the second dipole magnet 210 of FIG. 2, thus providing the desired achromaticity. By receiving and focusing the plurality of energetic portions 218A, 218B, 218C of the ion beam 204, substantially all of the so-called “energy spread” of the ion beam is passed to the second dipole magnet 210, whereby ion beam current is advantageously maintained.

FIG. 3 further illustrates the charge defining aperture 214, through which the ion beam 204 passes. The charge defining aperture 214, for example, comprises an opening 220 having a predetermined width 222 to accept and pass-through a predetermined energy spread (e.g., ±2%). In one example, the predetermined width 222 of the opening 220 can be varied based on the predetermined energy spread desired for a particular implantation. In another example, the charge defining aperture 214 permits all of the plurality of first energies to pass therethrough.

It is to be appreciated that, while the quadrupole apparatus 208 shown in FIG. 3 is illustrated as a magnetic quadrupole 224 (e.g., a quadrupole magnet), in an alternative aspect of the present disclosure, the quadrupole apparatus can comprise an electrostatic quadrupole (not shown). The magnetic quadrupole 224 illustrated in FIGS. 3, for example can provide advantages over an electrostatic quadrupole for tuning of the ion beam 204, as software associated with the system can ignore differences in magnetic and electrostatic rigidity when switching between different species of ion when implementing the magnetic quadrupole.

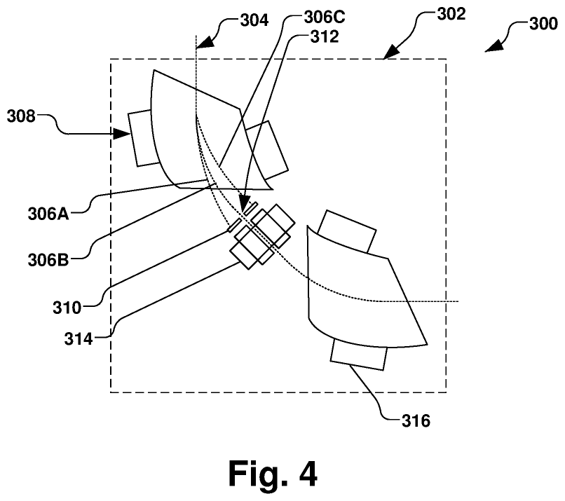

The present disclosure further provides charge filtering advantages over conventional systems, as will be discussed in reference to FIG. 4. For example, in another example 300 of a charge selector 302, an ion beam 304 (e.g., a mono-energetic ion beam) is provided having the same dimension and emittance as that shown in the ion beam 204 of FIGS. 2-3. However, the ion beam 304 of FIG. 4 is illustrated comprising a plurality of charge states 306A, 306B, 306C as the ion beam enters and passes through a first dipole magnet 308. In a non-limiting example, the ion beam 304 comprises an arsenic ion beam, wherein charge state 306A corresponds to As5+, charge state 306B corresponds to As6+, and charge state 306C corresponds to As7+.

Due to the various magnetic rigidities and dispersive properties of the first dipole magnet 308, for example, the plurality of charge states 306A, 306B, 306C are spatially separated after exiting the first dipole magnet. An aperture 310, for example, permits only a selected one of the plurality of charge states (e.g., charge state 306B or As6+) to pass through an opening 312 of the aperture into a quadrupole magnet 314 and second dipole magnet 316, while filtering out the remainder of the plurality of charge states.

Accordingly, the charge selector 302 provides charge filtering while also providing achromaticity via the quadrupole magnet 314, thus not only passing a predetermined energy spread associated with the plurality of energetic portions 218A, 2188, 218C of the ion beam 204 of FIG. 2, but also rejecting unwanted charge states and selectively passing on the selected one of the plurality of charge states through the opening 312 of the aperture 310 of FIG. 4. The aperture 310, for example, thus serves multiple purposes, as it not only rejects undesirable charge states, but by varying the width 222 of the opening 220 shown in FIG. 2, a predetermined energy spread can be further passed therethrough, thus providing a variable achromaticity associated with the charge selector.

The present disclosure further appreciates that, in order to attain a small footprint, the quadrupole apparatus 208 of FIG. 4, for example, may be positioned proximate to the first dipole magnet 206 and second dipole magnet 210 at a position that is less than twice the bending radius of either of the first and second dipole magnets. As such, fringe fields associated with dipole magnetic effects of the first and second dipole magnets 206, 210 and quadrupole apparatus 208 can affect the trajectories of the plurality of energetic portions 218A, 218B, 218C of the ion beam 204. As such, the quadrupole apparatus 208, for example, can be positioned to compensate for such trajectories and to advantageously pass the majority of the plurality of energetic portions of the ion beam therethrough.

For example, in an example homogeneous dipole magnet, the bending radius R of the ion beam 304 through the magnet, for example, is

$$R = \sqrt{\frac{2 mE}{Bq}} \qquad ( 1 ) ,$$

where m is the mass of the ion, E is the kinetic energy, B is the magnetic field and q is the charge of the ion. Calculating the relative change in bending radius dR/R for the both the charge case and energy case shows that dR/R=−dq/q and dR/R=0.5*dE/E, thus indicating that the spatial separation is approximately twice smaller in the energetic case. In addition, dE/E, for example, is approximately only 1-2% for LINACs, whereas dq/q, for example, can be approximately 17%. As such, a significantly larger spatial separation for the different charge states is advantageously provided in accordance with the present disclosure. It is to be further appreciated that, while the above example is for a total bending angle of 90°, a similar concept can be applied to smaller (e.g., 70°) or larger total bending angles (e.g., 360°).

Further, the present disclosure believes that steel associated with the quadruple magnet can have an affect on dipole fringe fields of the ion beam, thus causing the ion beam exiting the second dipole to be too convergent. In order to mitigate such a convergence, the quadrupole magnet of the present disclosure is slightly offset in the y1 dimension, thus achieving good parallelism (e.g., ±0.06° for dE=±5%). As such, in accordance with one example of the present disclosure, a dipole distance of 1.23*R can be used, which is more than three times smaller than conventional systems.

Furthermore, the present disclosure advantageously provides a small footprint for the system 100, whereby a small bending radius shown in FIGS. 3-4, for example, can employ high magnetic fields (e.g., 1.5 Tesla or greater).

Although the disclosure has been shown and described with respect to a certain applications and implementations, it will be appreciated that equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure, which performs the function in the herein illustrated exemplary implementations of the disclosure.

In addition, while a particular feature of the disclosure may have been disclosed with respect to only one of several implementations, such feature may be combined with one or more other features of the other implementations as may be desired and advantageous for any given or particular application. Furthermore, to the extent that the terms “includes”, “including”, “has”, “having”, and variants thereof are used in either the detailed description or the claims, these terms are intended to be inclusive in a manner similar to the term “comprising”.

What is claimed is:

1. An ion implantation system, comprising:
an ion source configured to generate ions and to define a generated ion beam along a beamline;
a mass analyzing magnet configured to mass analyze the generated ion beam, thereby defining a first ion beam comprising desired ions at a first charge state;
a first linear accelerator configured to accelerate the desired ions of the first ion beam to a plurality of first energies;
a charge stripper configured to strip at least one electron from the desired ions of the first ion beam, thereby defining a second ion beam comprising the desired ions at a plurality of second charge states;
a first dipole magnet configured to bend the second ion beam at a first predetermined angle, thereby spatially dispersing the second ion beam;
a charge defining aperture configured to pass a desired charge state of the second ion beam selected from the plurality of second charge states therethough, while blocking a remainder of the plurality of second charge states of the second ion beam from passing therethrough;
a quadrupole apparatus configured to spatially focus the second ion beam to define a third ion beam comprising the desired ions at the plurality of first energies and at the desired charge state;
a second dipole magnet configured to bend the third ion beam at a second predetermined angle;
a second linear accelerator configured to accelerate the desired ions of the third ion beam to a plurality of second energies; and
a final energy magnet comprising an energy defining aperture, wherein the final energy magnet is configured to bend the third ion beam at a third predetermined angle, and wherein the energy defining aperture is configured to pass only the desired ions at a desired energy therethrough, thereby defining a final ion beam comprising the desired ions at the desired energy and desired charge state.

2. The ion implantation system of claim 1, wherein the first predetermined angle and the second predetermined angle are approximately 45 degrees.

3. The ion implantation system of claim 1, wherein the third predetermined angle is approximately 90 degrees.

4. The ion implantation system of claim 1, wherein the charge defining aperture permits all of the plurality of first energies to pass therethrough.

5. The ion implantation system of claim 4, wherein the charge defining aperture is defined by an opening of the quadrupole apparatus through which the second ion beam enters the quadrupole apparatus.

6. The ion implantation system of claim 1, wherein the charge defining aperture is positioned between the first dipole magnet and the quadrupole apparatus along the beamline.

7. The ion implantation system of claim 1, wherein a width of the charge defining aperture permits only a predetermined dispersion of the plurality of first energies to pass into the quadrupole apparatus.

8. The ion implantation system of claim 7, wherein the width of the charge defining aperture is variable.

9. The ion implantation system of claim 1, wherein a sum of the first predetermined angle and the second predetermined angle is approximately 90 degrees.

10. The ion implantation system of claim 1, wherein the first predetermined angle and the second predetermined angle are equal and wherein the first dipole magnet and the second dipole magnet are generally mirror images of one another.

11. The ion implantation system of claim 10, wherein an exit of the first dipole magnet and an entrance of the second dipole magnet are separated by a predetermined separation distance, wherein the quadrupole apparatus is positioned between the first dipole magnet and the second dipole magnet at approximately half the predetermined separation distance.

12. The ion implantation system of claim 11, wherein the first predetermined angle defines a radius associated with the first dipole magnet, and wherein the predetermined separation distance is less than approximately twice the radius.

13. The ion implantation system of claim 1, further comprising:
a beam scanner configured to scan the final ion beam in a first direction, thereby defining a scanned ion beam; and
an angle corrector lens configured to parallelize and shift the scanned ion beam.

14. The ion implantation system of claim 1, wherein one or more of the first linear accelerator and the second linear accelerator comprise an RF accelerator comprising one or more resonators configured to generate an accelerating RF field.

15. The ion implantation system of claim 1, wherein one or more of the first linear accelerator and the second linear accelerator comprise DC accelerators configured to accelerate the desired ions via a stationary DC high voltage.

16. The ion implantation system of claim 1, wherein the quadrupole apparatus comprises a magnetic quadrupole.

17. The ion implantation system of claim 1, wherein the quadrupole apparatus comprises an electrostatic quadrupole.

18. The ion implantation system of claim 1, wherein the first dipole magnet and the second dipole magnet are symmetrically disposed with respect to one another.

19. The ion implantation system of claim 1, wherein the first dipole magnet and the second dipole magnet are asymmetrically disposed with respect to one another.

20. An ion implantation system, comprising:
a source of ions;
a first acceleration stage configured to accelerate the ions to define a first ion beam comprising the ions at a plurality of first energies;
a charge stripper configured to strip at least one electron from the ions of the first ion beam, thereby defining a second ion beam comprising the ions at the plurality of first energies at a plurality of second charge states;
a first dipole magnet configured to bend the second ion beam at a first predetermined angle, thereby spatially dispersing the second ion beam;
a charge defining aperture configured to pass only the ions at a desired charge state selected from the plurality of second charge states therethough;
a quadrupole apparatus configured to spatially focus the second ion beam to define a third ion beam comprising the ions at the plurality of first energies and at the desired charge state;
a second dipole magnet configured to bend the third ion beam at a second predetermined angle;
a second acceleration stage configured to accelerate the ions of the third ion beam to define a fourth ion beam comprising the ions at a plurality of second energies; and
a final energy magnet comprising an energy defining aperture, wherein the final energy magnet is configured to bend the fourth ion beam at a third predetermined angle, and wherein the energy defining aperture is configured to pass only the ions at a desired energy selected from the plurality of second energies therethrough, thereby defining a final ion beam comprising the ions at the desired energy and desired charge state.
